(19) United States
(12) Patent Application Publication
(10) Pub. No.: US 2026/0291196 A1
(43) Pub. Date: Sep. 24, 2026

(54) ELECTRICAL CONNECTION UNIT

(71) Applicant: Yazaki Corporation, Tokyo (JP)

(72) Inventor: Kazuhiro NAITO, Kakegawa-shi (JP)

(73) Assignee: Yazaki Corporation, Tokyo (JP)

(21) Appl. No.: 19/533,606

(22) Filed: Feb. 9, 2026

(30) Foreign Application Priority Data
Mar. 18, 2025 (JP) 2025-043482

(51) Int. Cl. H02G 3/16; H01R 4/34; H05K 7/20

(52) U.S. Cl. CPC H02G 3/16; H01R 4/34; H05K 7/2039

(57) ABSTRACT

An electrical connection unit according to an embodiment includes: an electronic component including a terminal; a wiring board including a base member and a bus bar held by the base member and having the electronic component mounted thereon; a heat transfer member including a first heat transfer surface and a second heat transfer surface; a metal member thermally connected to the second heat transfer surface; and a connection component integrally including a first portion fastened to the terminal, a second portion in contact with the first heat transfer surface, and a third portion fastened to the bus bar and electrically connecting the terminal and the bus bar.

### BACKGROUND OF THE INVENTION

### Field of the Invention

Embodiments of the present invention relate to an electrical connection unit.

Priority is claimed on Japanese Patent Application No. 2025-043482 filed in Japan on Mar. 18, 2025, the content of which is incorporated herein by reference.

### Description of Related Art

An electrical connection unit having an electronic component and a bus bar is known.

### Citation List

### Patent Literature

Patent Literature 1: Japanese Unexamined Patent Application, First Publication No. 2024-037492

### SUMMARY OF THE INVENTION

Improvement of heat dissipation properties of an electrical connection unit is expected.

One embodiment provides an electrical connection unit capable of improving heat dissipation properties.

An electrical connection unit according to an embodiment includes: an electronic component including a terminal; a wiring board including a base member and a bus bar held by the base member and having the electronic component mounted thereon; a heat transfer member including a first heat transfer surface and a second heat transfer surface; a metal member thermally connected to the second heat transfer surface; and a connection component integrally including a first portion fastened to the terminal, a second portion in contact with the first heat transfer surface, and a third portion fastened to the bus bar, and electrically connecting the terminal and the bus bar.

According to one embodiment, it is possible to improve heat dissipation properties.

### BRIEF DESCRIPTION OF THE DRAWINGS

FIG. 1 is a perspective view illustrating an electrical connection unit of an embodiment.

FIG. 2 is a perspective view illustrating an electronic component and a connection component of the embodiment.

FIG. 3 is a perspective view illustrating an electrical connection unit of a comparative example.

FIG. 4 is a perspective view illustrating an electrical connection unit according to a first modified example.

### DETAILED DESCRIPTION OF THE INVENTION

Hereinafter, an embodiment will be described with reference to the drawings. In the following description, constitutions having the same or similar functions are denoted by the same reference numbers. Redundant descriptions of these constitutions may be omitted. Furthermore, constitutions described below do not limit the scope of the embodiment.

In the present disclosure, the terms are defined as follows. The term “connection” is not limited to a mechanical connection and may include an electrical connection. That is, the term “connection” is not limited to a case where two elements that are connection targets are directly connected, and may include a case where two elements that are connection targets are connected with another element interposed therebetween. The term “facing” indicates that virtual projection images of two target objects overlap each other when viewed from a specific direction. That is, the term “facing” is not limited to a case where two target objects directly face each other, and may include a case where two target objects face each other in a state where another member exists between the two target objects. “Orthogonal” or “the same” may also include “substantially orthogonal” or “substantially the same”, respectively. “Sheet-shaped” or “sheet” is not limited to a member having a thickness of 1 mm or more, and a member (e.g., a film) having a thickness of less than 1 mm can also be used.

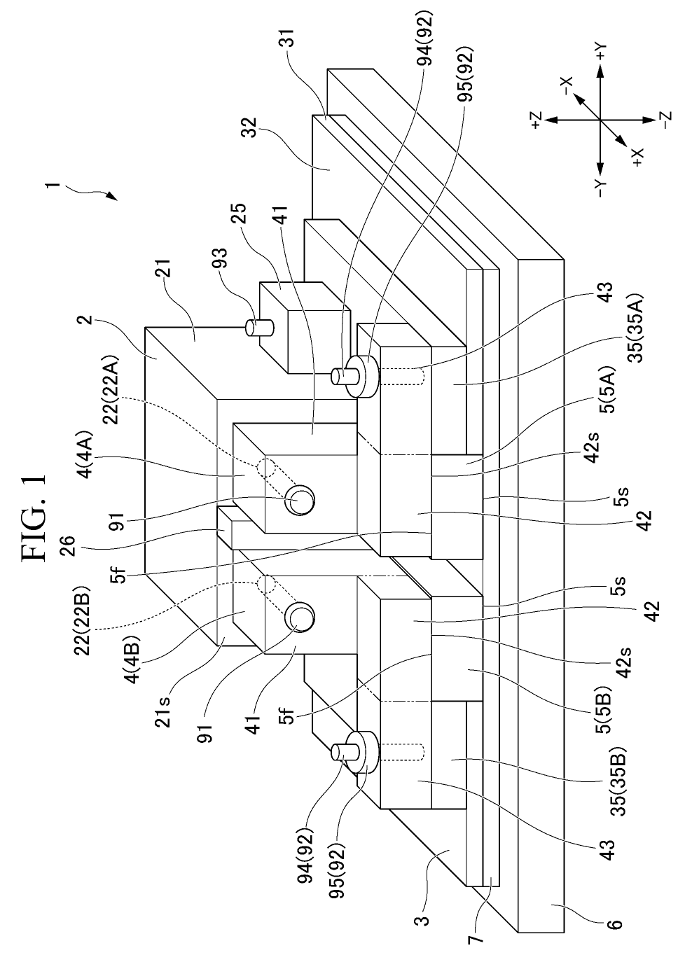

As illustrated in FIG. 1, in this disclosure, the +X direction, -X direction, +Y direction, -Y direction, +Z direction, and -Z direction are defined as follows: The X direction is a direction in which a flat surface portion 32 of a base plate 31 described below extends. The +X direction is one side of the X direction. The -X direction is a direction opposite to the +X direction. Hereinafter, when the +X direction and the -X direction are not distinguished from each other, they are simply referred to as “X direction”. The Y direction is a direction in which the flat surface portion 32 of the base plate 31 to be described below extends and is a direction intersecting (for example, orthogonal to) the X direction. The +Y direction is one side of the Y direction. The -Y direction is a direction opposite to the +Y direction. Hereinafter, when the +Y direction and the -Y direction are not distinguished from each other, they are simply referred to as “Y direction”. The Z direction is a thickness direction of the flat surface portion 32 of the base plate 31 and is a direction intersecting (for example, orthogonal to) the X direction and the Y direction. The +Z direction is one side of the Z direction. The -Z direction is a direction opposite to the +Z direction. Hereinafter, when the +Z direction and the -Z direction are not distinguished from each other, they are simply referred to as “Z direction”. The X direction is an example of a “third direction”. The Y direction is an example of a “second direction”. The Z direction is an example of a “first direction”.

Hereinafter, when the X direction and the Y direction are not distinguished from each other, they may be referred to as “horizontal direction”. Hereinafter, the Z direction may be referred to as “vertical direction”. Hereinafter, the +Z direction side may be referred to as “upper”, and the -Z direction side may be referred to as “lower”. However, these expressions are expressions for convenience of description, and do not limit a gravity direction of an electrical connection unit 1 (an installation orientation of the electrical connection unit 1).

### EMBODIMENT

### 1. CONFIGURATION OF ELECTRICAL CONNECTION UNIT

The electrical connection unit 1 is, for example, an in-vehicle device mounted on a vehicle such as an electric vehicle (EV), a hybrid electric vehicle (HEV), or a plug-in hybrid electric vehicle (PHEV). For example, the electrical connection unit 1 may be referred to as an “electrical connection box” or a “junction box”. However, the electrical connection unit 1 is not limited to a box-shaped device.

The electrical connection unit 1 is electrically connected to an external device. In the present disclosure, the “external device” is an electrical device existing outside the electrical connection unit 1. The external device is, for example, a battery unit mounted on a vehicle or an inverter for driving a motor of the vehicle, but is not limited to these examples.

The electrical connection unit 1 includes an electronic component 2, a wiring board 3, a pair of connection components 4, a pair of heat transfer members 5, a metal plate 6, an insulating sheet 7, a fastening member 91, and a fastening member 93.

### 2. ELECTRONIC COMPONENT

First, the electronic component 2 will be described.

The electronic component 2 is an electronic component mounted on the wiring board 3 according to a function required for the electrical connection unit 1. The electronic component 2 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. The electronic component 2 is provided on the +Z direction side of the wiring board 3. For example, the electronic component 2 may be mounted on the flat surface portion 32 of the base plate 31 described below from the +Z direction side of the flat surface portion 32. Furthermore, the type of the electronic component 2 is not limited to the above example. The electronic component 2 is, for example, a heat generating component that generates heat at the time of energization. The electronic component 2 includes, for example, a main body 21, a pair of terminals 22, and an attachment portion 25. For example, the electronic component 2 may further include an insulating rib 26 between the pair of terminals 22.

### Main body

The main body 21 is a portion that performs a main function of the electronic component 2. For example, in a case where the electronic component 2 is a relay, the main body 21 includes a switch (for example, a contact) that switches between a conductive state and a non-conductive state. For example, in a case where the electronic component 2 is a fuse, the main body 21 includes a fusible portion that melts when an overcurrent flows. For example, in a case where the electronic component 2 is a capacitor, the main body 21 includes a portion that accumulates electric charge. The main body 21 is made of, for example, a synthetic resin and has insulating properties. The main body 21 has a side surface 21s facing the +X direction. For example, the side surface 21s may be a flat surface.

### Terminal

The pair of terminals 22 are located on the +X direction side of the main body 21. The pair of terminals 22 are arranged in the Y direction. The terminal 22 is an electrical connection portion exposed to the outside of the main body 21. Each terminal 22 is electrically connected to the inside of the main body 21. Each terminal 22 may have, for example, a screw hole that opens in the X direction and extends in the X direction so that the fastening member 91 (for example, a screw or a bolt) is attached.

In the present embodiment, the electronic component 2 includes a terminal 22A and a terminal 22B as the pair of terminals 22. One of the terminal 22A and the terminal 22B may be, for example, a terminal on the positive electrode side. The other of the terminal 22A and the terminal 22B may be, for example, a terminal on the negative electrode side. Hereinafter, when the terminal 22A and the terminal 22B are not distinguished from each other, they are simply referred to as “terminal 22”.

### Attachment portion

The attachment portion 25 is a portion for fixing the electronic component 2 to the wiring board 3. The attachment portion 25 may be fixed to the wiring board 3 by, for example, the fastening member 93 (for example, a screw or a bolt) inserted into the attachment portion 25 from the +Z direction side of the attachment portion 25.

### Insulating rib

The insulating rib 26 protrudes in the +X direction from the side surface 21s of the main body 21. The insulating rib 26 extends over the entire side surface 21s in the Z direction. The insulating rib 26 ensures electrical insulation between the terminal 22A and the terminal 22B.

### 3. WIRING BOARD

Next, the wiring board 3 will be described.

The wiring board 3 is a member that forms at least part of the electrical path between the electronic component 2 and other components (connectors, electronic components, devices, wiring members, etc.). In the present disclosure, the “wiring board” indicates a board type wiring structure. The “board type” indicates a plate shape along one plane when viewed as a whole regardless of a fine shape. In the present disclosure, the “plate shape” is not limited to a completely flat shape, and may include a case where a fixing structure, a rib, or the like protruding in the Z direction is partially present. In the present embodiment, the wiring board 3 has a plate shape formed in the X direction and the Y direction.

The wiring board 3 includes, for example, the base plate 31, a pair of bus bars 35, and a pair of fastening members 92. The pair of bus bars 35 is fixed to the base plate 31. In the present embodiment, the base plate 31 and the pair of bus bars 35 are integrated with each other.

### Fastening member

Each fastening member 92 fastens the connection component 4 and the bus bar 35. The fastening member 92 may include, for example, a stud bolt 94 and a nut 95. The fastening member 92 is an example of a “second fastening portion”.

### Base plate

The base plate 31 is a holding member that integrally holds the pair of bus bars 35 that are arranged horizontally with a gap between them. The base plate 31 is made of, for example, synthetic resin and has insulating properties. The base plate 31 provides electrical insulation between the pair of bus bars 35. The base plate 31 is an example of a “base member”. The base plate 31 may also be referred to as an “insulating substrate”. The base plate 31 has the flat surface portion 32.

The flat surface portion 32 is a portion of the base plate 31 that is formed in a plate shape. The flat surface portion 32 is in the form of a plate extending in the horizontal direction. The flat surface portion 32 forms the main portion of the base plate 31. The flat surface portion 32 forms the base portion (insulating base portion) of the base plate 31. In the present embodiment, the flat surface portion 32 may extend across the entire width of the base plate 31 in the X direction and across the entire width of the base plate 31 in the Y direction, for example. The flat surface portion 32 faces the metal plate 6 via the insulating sheet 7. The flat surface portion 32 has a thickness in the Z direction. For example, the electronic component 2 may be mounted on the flat surface portion 32.

### Bus bar

Each bus bar 35 is a wiring member (electrical connection member) included in the wiring board 3. The bus bar 35 is, for example, a wiring member for electrically connecting the electronic component 2 to other components (connectors, electronic components, devices, wiring members, etc.). The bus bar 35 is made of metal (for example, copper or a copper alloy) and is electrically conductive. In the present embodiment, the pair of bus bars 35 include portions that are arranged on the same plane. Each bus bar 35 is held by the flat surface portion 32 of the base plate 31.

At least a part of each bus bar 35 is in a plate shape extending in the horizontal direction. That is, at least a part of each bus bar 35 extends along the flat surface portion 32. In the present embodiment, each bus bar 35 is in the form of a plate extending horizontally across the entire bus bar 35. The bus bar 35 is a member that forms a horizontal electrical path. The bus bar 35 may also be referred to as a “horizontal wiring member”. A bus bar 35A of the pair of bus bars 35 is fastened to a third portion 43 of a connection component 4A, which will be described below. A bus bar 35B of the pair of bus bars 35 is fastened to the third portion 43 of a connection component 4B, which will be described below.

### 4. FASTENING MEMBER

The fastening member 91 is a component for fixing each connection component 4 to the electronic component 2. For example, the fastening member 91 may be a screw or a bolt extending long in the X direction. The fastening member 91 is an example of a first fastening portion.

The fastening member 93 is a component for fixing the electronic component 2 to the wiring board 3. For example, the fastening member 93 may be a screw or a bolt extending long in the Z direction. The fastening member 93 is an example of a third fastening portion.

### 5. CONNECTION COMPONENT

Each connection component 4 is a component that electrically connects the terminal 22 of the electronic component 2 and the bus bar 35 of the wiring board 3. Each connection component 4 forms a part of the electrical path in the electrical connection unit 1. Each connection component 4 is provided on the +Z direction side of the wiring board 3. Each connection component 4 is provided on the +X direction side of the main body 21 of the electronic component 2. Each connection component 4 is made of metal (for example, copper or a copper alloy). Each connection component 4 may be referred to as a “metal component”. Each connection component 4 integrally includes a first portion 41, a second portion 42, and a third portion 43. Each connection component 4 may be, for example, a block body integrally including the first portion 41, the second portion 42, and the third portion 43. Each connection component 4 may have an L shape when viewed from any of the X, Y and Z directions, for example. Each connection component 4 may be referred to as a “vertical wiring member”.

Each connection component 4 is, for example, a thermal mass block having a function of increasing the heat capacity of the electrical path of the electrical connection unit 1. Each connection component 4 stores (absorbs) at least a part of heat generated by the electronic component 2, for example. Alternatively or additionally, each connection component 4 may store (absorb) at least a part of heat generated by the bus bar 35 due to energization. Each connection component 4 may be referred to as a “heat storage component” or a “heat absorbing component”.

In the present embodiment, the electrical connection unit 1 includes the connection component 4A and the connection component 4B as the pair of connection components 4. The connection component 4A may be connected to the terminal 22A, for example. The connection component 4B may be connected to the terminal 22B, for example. Hereinafter, when the connection component 4A and the connection component 4B are not distinguished from each other, they are simply referred to as “connection component 4”.

### First portion

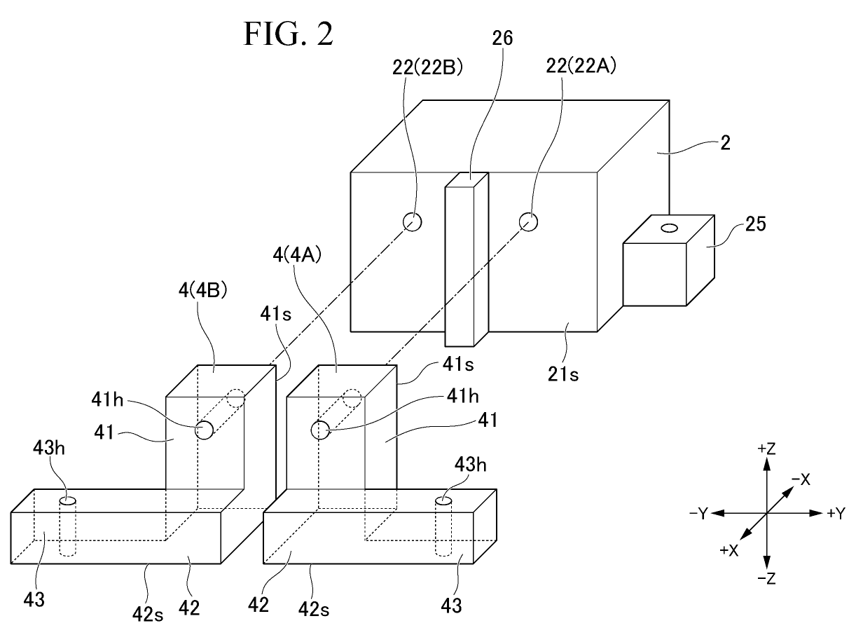

The first portion 41 of the connection component 4 is a portion that is electrically and physically connected to the terminal 22 of the electronic component 2. The first portion 41 is fastened to the terminal 22 of the electronic component 2. The first portion 41 is a rectangular parallelepiped block-shaped portion of the connection component 4. The first portion 41 extends longer in the Z direction than in the X direction and the Y direction. A side surface 41s of the first portion 41 facing the -X direction faces the side surface 21s of the main body 21 (see FIG. 2). The side surface 41s may be in surface contact with the side surface 21s, for example. For example, the side surface 41s and the side surface 21s may be planar with each other. The first portion 41 extends along the side surface 21s of the main body 21 in the Z direction. The first portion 41 is an upright portion that stands upright in the Z direction relative to the wiring board 3 (and relative to a heat transfer member 5). The first portion 41 is adjacent to the +X direction side of the main body 21. The first portion 41 is fastened to the associated terminal 22 in the +X direction.

In the present embodiment, the thickness of at least a part of the first portion 41 in the X direction is larger than the thickness of the bus bar 35 in the Z direction. Furthermore, the width of at least a part of the first portion 41 in the Y direction is larger than the thickness of the bus bar 35 in the Z direction.

The first portion 41 of the connection component 4A may have a thickness in the X direction that is larger than the thickness in the Z direction of the bus bar 35A fastened to the connection component 4A, for example, over the entire length of the first portion 41 in the Z direction. The first portion 41 of the connection component 4A may have a width in the Y direction that is larger than the thickness in the Z direction of the bus bar 35A that is fastened to the connection component 4A, for example, over the entire length of the first portion 41 in the Z direction.

The first portion 41 of the connection component 4B may have a thickness in the X direction that is larger than the thickness in the Z direction of the bus bar 35B fastened to the connection component 4B, for example, over the entire length of the first portion 41 in the Z direction. The first portion 41 of the connection component 4B may have a width in the Y direction that is larger than the thickness in the Z direction of the bus bar 35B fastened to the connection component 4B, for example, over the entire length of the first portion 41 in the Z direction.

As illustrated in FIG. 2, the first portion 41 has a first attachment hole 41h. The first attachment hole 41h is opened in the X direction. The first attachment hole 41h penetrates in the X direction. The fastening member 91 is passed through the first attachment hole 41h from the +X direction side of the first attachment hole 41h (see FIG. 1). The first portion 41 is physically and electrically connected to the associated terminal 22 by the fastening member 91 passing through the first attachment hole 41h engaging with the screw hole of the terminal 22 of the electronic component 2.

### Second portion

As illustrated in FIG. 1, the second portion 42 of each connection component 4 is a portion that is thermally connected to the associated heat transfer member 5 of the pair of heat transfer members 5. The second portion 42 of each connection component 4 is in contact with the associated heat transfer member 5 of the pair of heat transfer members 5. In each connection component 4, the second portion 42 is closer to the first portion 41 than the third portion 43. In each connection component 4, the second portion 42 protrudes in the +X direction from the end of the first portion 41 on the -Z direction side.

In each connection component 4, the combined portion of the second portion 42 and the third portion 43 has a rectangular parallelepiped shape that is longer in the Y direction than in the Z direction and the X direction as a whole. In each connection component 4, the second portion 42 is a rectangular parallelepiped block-shaped portion that is closer to the first portion 41 than the combined portion of the second portion 42 and the third portion 43. The second portion 42 extends longer in the Y direction than in the Z direction and the X direction.

The second portion 42 of the connection component 4A is a portion that extends in the -Y direction from the third portion 43 of the connection component 4A. Further, the second portion 42 of the connection component 4B is a portion that extends in the +Y direction from the third portion 43 of the connection component 4B.

In the present embodiment, the thickness in the Z direction of at least a part of the second portion 42 is larger than the thickness in the Z direction of the associated bus bar 35 of the pair of bus bars 35. The width in the X direction of at least a part of the second portion 42 is larger than the thickness in the Z direction of the associated bus bar 35 of the pair of bus bars 35.

The second portion 42 of the connection component 4A may have a thickness in the Z direction that is larger than the thickness in the Z direction of the bus bar 35A fastened to the connection component 4A, for example, over the entire length of the second portion 42 in the Y direction. The second portion 42 of the connection component 4A may have, for example, a width in the X direction that is larger than the thickness in the Z direction of the bus bar 35A fastened to the connection component 4A over the entire length of the second portion 42 in the Y direction.

The second portion 42 of the connection component 4B may have a thickness in the Z direction that is larger than the thickness in the Z direction of the bus bar 35B fastened to the connection component 4B, for example, over the entire length of the second portion 42 in the Y direction. The second portion 42 of the connection component 4B may have, for example, a width in the X direction that is larger than the thickness in the Z direction of the bus bar 35B fastened to the connection component 4B over the entire length of the second portion 42 in the Y direction.

The second portion 42 is adjacent to the +Z direction side of the associated heat transfer member 5. The second portion 42 is in contact with the associated heat transfer member 5 from the Z direction. For example, the second portion 42 may be in contact with the associated heat transfer member 5 from the +Z direction side of the heat transfer member 5. The second portion 42 has a contact surface 42s facing the -Z direction. The contact surface 42s faces a first heat transfer surface 5f to be described below of the associated heat transfer member 5. The contact surface 42s presses the first heat transfer surface 5f. The contact surface 42s is thermally connected to the first heat transfer surface 5f. The contact surface 42s is in surface contact with the first heat transfer surface 5f. For example, the contact surface 42s may be a flat surface. For example, the surface of the connection component 4 facing the -Z direction (including the contact surface 42s) from the first portion 41 to the second portion 42 may be a flush plane. For example, the surface of the connection component 4 facing the -Z direction (including the contact surface 42s) may be in contact with the associated heat transfer member 5 across the first portion 41 to the second portion 42.

### Third Portion

The third portion 43 of each connection component 4 is a portion that is electrically and physically connected to the associated bus bar 35 of the pair of bus bars 35. The third portion 43 is fastened to the bus bar 35. The third portion 43 is in contact with the associated bus bar 35. The third portion 43 is farther from the first portion 41 than the second portion 42. The second portion 42 and the third portion 43 are arranged in the Y direction.

The third portion 43 of each connection component 4 is adjacent to the second portion 42 in the Y direction. The third portion 43 of the connection component 4A is adjacent to the +Y direction side of the second portion 42 of the connection component 4A. The third portion 43 of the connection component 4B is adjacent to the -Y direction side of the second portion 42 of the connection component 4B.

The third portion 43 is a rectangular parallelepiped block-shaped portion on a side far from the first portion 41 in the combined portion of the second portion 42 and the third portion 43. The third portion 43 extends longer in the Y direction than in the Z direction and the X direction.

The third portion 43 of the connection component 4A is a portion continuously extending from the second portion 42 of the connection component 4A in the +Y direction. The third portion 43 of the connection component 4B is a portion continuously extending from the second portion 42 of the connection component 4B in the -Y direction.

The thickness of the third portion 43 in the Z direction may be, for example, the same as the thickness of the second portion 42 in the Z direction over the entire length of the third portion 43 in the Y direction. The thickness of the third portion 43 in the X direction may be, for example, the same as the thickness of the second portion 42 in the X direction over the entire length of the third portion 43 in the Y direction.

In the present embodiment, the thickness in the Z direction of at least a part of the third portion 43 is larger than the thickness in the Z direction of the associated bus bar 35 of the pair of bus bars 35. The width in the X direction of at least a part of the third portion 43 is larger than the thickness in the Z direction of the associated bus bar 35 in the pair of bus bars 35.

For example, the third portion 43 of the connection component 4A may have a thickness in the Z direction larger than the thickness in the Z direction of the bus bar 35A fastened to the connection component 4A over the entire length in the Y direction of the third portion 43. For example, the third portion 43 of the connection component 4A may have a thickness in the X direction larger than the thickness in the Z direction of the bus bar 35A fastened to the connection component 4A over the entire length in the Y direction of the third portion 43.

For example, the third portion 43 of the connection component 4B may have a thickness in the Z direction larger than the thickness in the Z direction of the bus bar 35B fastened to the connection component 4B over the entire length in the Y direction of the third portion 43. For example, the third portion 43 of the connection component 4B may have a thickness in the X direction larger than the thickness in the Z direction of the bus bar 35B fastened to the connection component 4B over the entire length in the Y direction of the third portion 43.

As illustrated in FIG. 2, the third portion 43 has a second attachment hole 43h. The second attachment hole 43h is open in the Z direction. The second attachment hole 43h penetrates in the Z direction. The stud bolt 94 passes through the second attachment hole 43h from the -Z direction side of the second attachment hole 43h.

As illustrated in FIG. 1, the third portion 43 is adjacent to the +Z direction side of the associated bus bar 35. The third portion 43 is in contact with the associated bus bar 35 from the +Z direction side of the bus bar 35. The third portion 43 is physically and electrically connected to the associated bus bar 35 by engaging a nut 95 with the tip of the stud bolt 94 passed through the second attachment hole 43h. The third portion 43 is fastened to the bus bar 35 by the stud bolt 94 and the nut 95 from the +Z direction. The nut 95 is passed through the stud bolt 94 from the +Z direction side of the stud bolt 94. The nut 95 is fastened to the stud bolt 94 from the +Z direction side toward the bus bar 35.

### 6. HEAT TRANSFER MEMBER

Next, the heat transfer member 5 will be described.

The pair of heat transfer members 5 is members for transmitting heat generated by the electronic component 2 to the metal plate 6 via the connection component 4. Each of the heat transfer members 5 is, for example, a heat transfer sheet (for example, a thermally conductive silicone sheet) having elasticity. However, each heat transfer member 5 is not limited to the above example, and may be a heat transfer member made of a thermally conductive gel or other materials. Each heat transfer member 5 may transfer the stored heat of the connection component 4 to the metal plate 6, for example. For example, each heat transfer member 5 may transfer heat generated by the bus bar 35 during energization to the metal plate 6 via the connection component 4.

The heat transfer member 5A of the pair of heat transfer members 5 is disposed between the second portion 42 of the connection component 4A and the insulating sheet 7. The heat transfer member 5A is in contact with the insulating sheet 7 from the +Z direction side of the insulating sheet 7. The heat transfer member 5A is in contact with the second portion 42 of the connection component 4A from the -Z direction side of the second portion 42.

The heat transfer member 5B of the pair of heat transfer members 5 is disposed between the second portion 42 of the connection component 4B and the insulating sheet 7. The heat transfer member 5B is in contact with the insulating sheet 7 from the +Z direction side of the insulating sheet 7. The heat transfer member 5B is in contact with the second portion 42 of the connection component 4B from the -Z direction side of the second portion 42. Hereinafter, when the heat transfer member 5A and the heat transfer member 5B are not distinguished from each other, they are simply referred to as “heat transfer member 5”.

The heat transfer member 5 has a thickness in the Z direction. The heat transfer member 5 has a first heat transfer surface 5f and a second heat transfer surface 5s. The first heat transfer surface 5f faces the +Z direction. The second heat transfer surface 5s faces the -Z direction. The first heat transfer surface 5f faces the contact surface 42s of the associated second portion 42. The first heat transfer surface 5f is in surface contact with the contact surface 42s of the associated second portion 42 so as to allow heat transfer between the connection component 4 and the heat transfer member 5. The second heat transfer surface 5s faces the metal plate 6 via the insulating sheet 7. The second heat transfer surface 5s is in surface contact with the insulating sheet 7 so that heat can be transferred between the heat transfer member 5 and the metal plate 6.

In the present embodiment, the first heat transfer surface 5f of the heat transfer member 5A faces the contact surface 42s of the second portion 42 of the connection component 4A. The first heat transfer surface 5f of the heat transfer member 5A is in surface contact with the contact surface 42s of the second portion 42 of the connection component 4A.

In the present embodiment, the first heat transfer surface 5f of the heat transfer member 5B faces the contact surface 42s of the second portion 42 of the connection component 4B. The first heat transfer surface 5f of the heat transfer member 5B is in surface contact with the contact surface 42s of the second portion 42 of the connection component 4B.

For example, the heat transfer member 5 may extend from the first portion 41 to the second portion 42 of the associated connection component 4 on the -Z direction side of the connection component 4. The first heat transfer surface 5f of the heat transfer member 5 may be in surface contact with a surface facing the -Z direction side including the contact surface 42s of the associated connection component 4, for example, from the first portion 41 to the second portion 42 of the associated connection component 4.

### 7. METAL PLATE

Next, the metal plate 6 will be described.

The metal plate 6 is thermally connected to the second heat transfer surface 5s. The metal plate 6 is a member for ensuring rigidity of the electrical connection unit 1 and improving heat dissipation properties of the electrical connection unit 1. The metal plate 6 is made of a metal (for example, aluminum or an aluminum alloy). The metal plate 6 is an example of a “metal member”. When viewed from the Z direction, the metal plate 6 has a rectangular shape with sides in the X and Y directions. The metal plate 6 may be a plate along the horizontal direction.

### 8. INSULATING SHEET

Next, the insulating sheet 7 will be described.

The insulating sheet 7 is an insulating member for electrically insulating the metal plate 6 from the wiring board 3. The insulating sheet 7 is made of, for example, a synthetic resin such as polyester or polyimide, and has an insulating properties. The insulating sheet 7 has a rectangular shape having sides in the X direction and the Y direction when viewed from the Z direction. The insulating sheet 7 has a sheet shape formed in the horizontal direction. The insulating sheet 7 is disposed between the metal plate 6 and the wiring board 3. The insulating sheet 7 is disposed between the metal plate 6 and the heat transfer member 5. The insulating sheet 7 thermally connects the metal plate 6 and the heat transfer member 5.

### 9. ADVANTAGES

According to the electrical connection unit 1 of the present embodiment, in the connection component 4 that electrically connects the terminal 22 and the bus bar 35, the second portion 42 is in contact with the first heat transfer surface 5f. With such a configuration, heat generated in the electronic component 2 can be dissipated from the connection component 4 to the metal plate 6. Therefore, it is easy to dissipate heat generated in the electronic component 2.

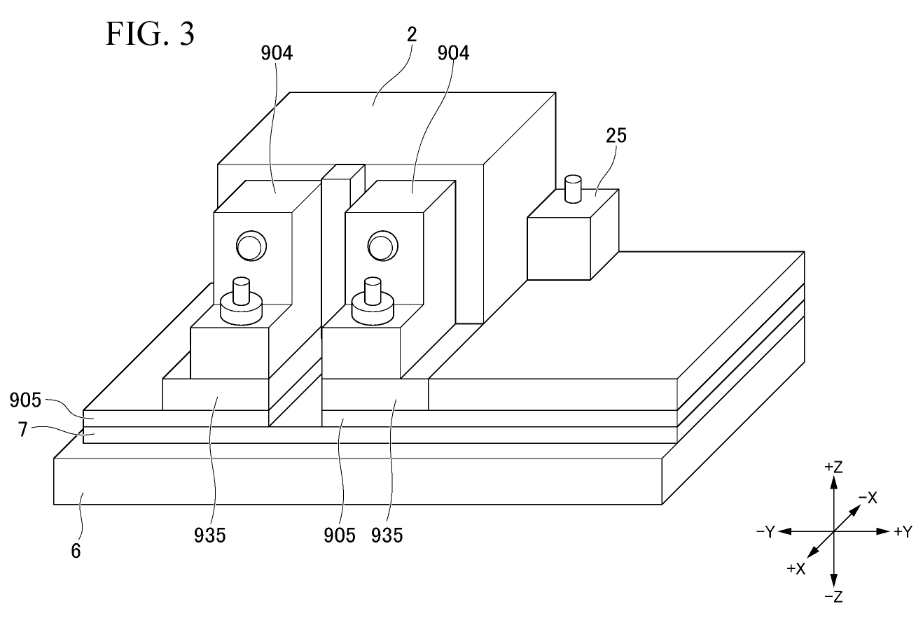

As a comparative example, there is an electrical connection unit in which a bus bar 935, a heat transfer member 905, and an insulating sheet 7 are laminated between a connection component 904 and a metal plate 6 as shown in FIG. 3. In the case of the electrical connection unit of this comparative example, heat generated in electronic component 2 is dissipated to the heat transfer member 905 via a heat path that includes at least the bus bar 935. Due to this heat path, in the comparative example, it is difficult to dissipate the heat generated in the electronic component 2.

In contrast to this comparative example, according to the electrical connection unit 1 of the present embodiment, heat generated in the electronic component 2 can be dissipated to the metal plate 6 via the heat path that does not include the bus bar 935. Due to this heat path, it is easy to dissipate heat generated in the electronic component 2. Therefore, it is possible to improve heat dissipation properties.

Furthermore, according to the electrical connection unit 1 of the present embodiment, the second portion 42 in contact with the first heat transfer surface 5f and the third portion 43 fastened to the bus bar 35 are aligned in the Y direction. With such a configuration, the fastening portion between the bus bar 35 and the connection component 4 and the contact portion between the heat transfer member 5 and the connection component 4 can be separated. Therefore, it is possible to ensure contact between the heat transfer member 5 and the connection component 4 without being affected by the fastening portion.

As a comparative example, in an electrical connection unit such as that illustrated in FIG. 3, if a stud bolt or the like is used as a fastening portion of the bus bar 935 and the connection component 904, a protrusion (fillet) may occur on the surface of the bus bar 935 facing the heat transfer member 905. When such a protrusion is generated, contact between the heat transfer member 905 and the connection component 904 may not be ensured.

In contrast to this comparative example, the electrical connection unit 1 of the present embodiment can ensure contact between the heat transfer member 5 and the connection component 4 without being affected by the fastening portion as described above.

According to the electrical connection unit 1 of the present embodiment, in each connection component 4, the second portion 42 is closer to the first portion 41 than the third portion 43. According to such a configuration, each connection component 4 can dissipate heat to the heat transfer member 5 at a position close to the first portion 41. Therefore, it is easy to dissipate heat generated in the electronic component 2.

Furthermore, according to the electrical connection unit 1 of the present embodiment, the third portion 43 is closer to the second portion 42 than the attachment portion 25. With this configuration, the amount of compression of the heat transfer member 5 can be controlled by the fastening pressure at the third portion 43.

As a comparative example, in the case of the electrical connection unit as illustrated in FIG. 3, the amount of compression of the heat transfer member 905 is controlled by the fastening pressure at the attachment portion 25. However, since the attachment portion 25 is far from the fastening portion between the bus bar 935 and the connection component 904, it is difficult to control the amount of compression of the heat transfer member 905.

On the other hand, according to the electrical connection unit 1, as described above, the connection component 4 is fastened to the bus bar 35 in the third portion 43 closer to the second portion 42 than the attachment portion 25. Therefore, it is easy to manage the amount of compression of the heat transfer member 5.

In the connection component 4 of the present embodiment, each of the first portion 41, the second portion 42, and the third portion 43 has a rectangular parallelepiped block shape. With such a shape, the connection component 4 can function as a heat mass block (heat storage member). With such a function, a temperature change in the electrical connection unit 1 can be suppressed. Therefore, the thermal characteristics of the electrical connection unit can be improved.

According to the electrical connection unit 1 of the present embodiment, the first heat transfer surface 5f of the heat transfer member 5 is in surface contact, for example, from the first portion 41 to the second portion 42, on the surface facing the -Z direction including the contact surface 42s of the connection component 4.

As a comparative example, in the electrical connection unit as illustrated in FIG. 3, the bus bar 935 immediately below each terminal of the electronic component 2 is located far from the fastening portion. With this configuration, there is a possibility that the bus bar 935 is not in close contact with the heat transfer member 905.

In contrast to this comparative example, in the electrical connection unit 1 of the present embodiment, close contact between the bus bar 35 and the heat transfer member 5 is not required. On the other hand, in the electrical connection unit 1, the connection component 4 is in surface contact with the heat transfer member 5 from the first portion 41 to the second portion 42. Therefore, it is easy to dissipate heat generated in the electronic component 2.

### 10. MODIFIED EXAMPLES

Next, several modified examples will be described. Furthermore, the configurations of each of the modified examples other than those described below are the same as those of the above-described embodiment.

### First modified example

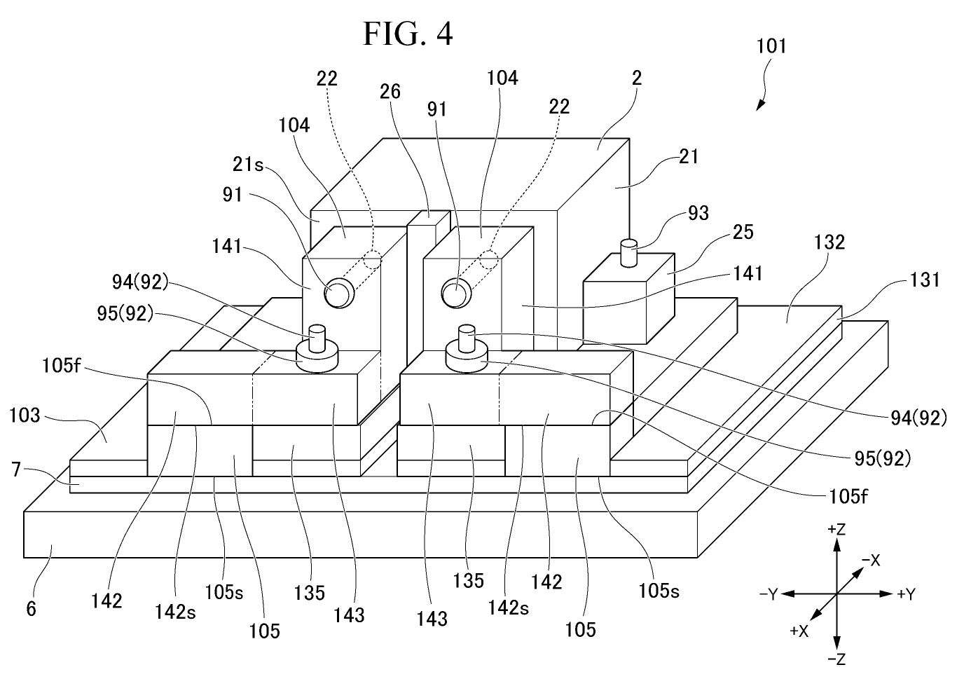

In the above-described embodiment, in the electrical connection unit 1, the second portion 42 is configured to be closer to the first portion 41 than the third portion 43. However, any configuration may be used as long as the heat generated in the electronic component 2 can be dissipated to the metal plate 6 via a heat path that does not include a bus bar. As a first modified example, as illustrated in FIG. 4, in the electrical connection unit, the second portion may be configured to be farther from the first portion than the third portion. A detailed configuration will be described below.

### Configuration of first modified example

An electrical connection unit 101 illustrated in FIG. 4 has the same configuration as the electrical connection unit 1 except that the configurations of the wiring board, the connection component, and the heat transfer member are different. The electrical connection unit 101 includes the electronic component 2, a wiring board 103, a pair of connection components 104, a pair of heat transfer members 105, the metal plate 6, the insulating sheet 7, the fastening member 91, and the fastening member 93.

The wiring board 103 includes, for example, a base plate 131, a pair of bus bars 135, and the pair of fastening members 92. The base plate 131 and the pair of bus bars 135 have the same configuration as the base plate 31 and the pair of bus bars 35 except for the following points.

The pair of bus bars 135 are fixed to the base plate 131. Each bus bar 135 is held by a flat surface portion 132 of the base plate 131. Each bus bar 135 is fastened to a third portion 143 to be described below of the associated connection component 104.

Each connection component 104 integrally includes a first portion 141, a second portion 142, and a third portion 143. The first portion 141 of each connection component 104 is connected to the associated terminal 22. The connection component 104 has the same configuration as the connection component 4 except for the following points.

The second portion 142 of each connection component 104 is a portion that is thermally connected to the associated heat transfer member 105 of the pair of heat transfer members 105. The second portion 142 of each connection component 104 is in contact with the associated heat transfer member 105 of the pair of heat transfer members 105. In each connection component 104, the second portion 142 is farther from the first portion 141 than the third portion 143.

The second portion 142 is adjacent to the +Z direction side of the associated heat transfer member 105. The second portion 142 is in contact with the associated heat transfer member 105 from the +Z direction of the heat transfer member 105. The second portion 142 has a contact surface 142s facing the -X direction. The contact surface 142s faces a first heat transfer surface 105f to be described below of the associated heat transfer member 105. The contact surface 142s presses the first heat transfer surface 105f. The contact surface 142s is thermally connected to the first heat transfer surface 105f. The contact surface 142s is in surface contact with the first heat transfer surface 105f.

The third portion 143 of each connection component 104 is a portion that is electrically and physically connected to the associated bus bar 135 of the pair of bus bars 135. The third portion 143 is fastened to the associated bus bar 135. The third portion 143 is in contact with the associated bus bar 135. The third portion 143 is closer to the first portion 141 than the second portion 142. The second portion 142 and the third portion 143 are arranged in the Y direction.

The third portion 143 of each connection component 104 is adjacent to the second portion 142 in the Y direction. In each connection component 104, the third portion 143 protrudes in the +X direction from the end of the first portion 141 on the -Z direction side.

The pair of heat transfer members 105 are members for transferring heat generated by the electronic component 2 to the metal plate 6 via the connection component 104.

Each heat transfer member 105 is arranged between the second portion 142 of the associated connection component 104 and the insulating sheet 7. The heat transfer member 105 is in contact with the insulating sheet 7. The heat transfer member 105 is in contact with the second portion 142 of the associated connection component 104.

The heat transfer member 105 has a first heat transfer surface 105f and a second heat transfer surface 105s. The first heat transfer surface 105f faces the +Z direction. The second heat transfer surface 105s faces the -Z direction. The first heat transfer surface 105f faces the contact surface 142s of the associated second portion 142. The first heat transfer surface 105f is in surface contact with the contact surface 142s of the associated second portion 142 so as to allow heat transfer between the connection component 104 and the heat transfer member 105. The second heat transfer surface 105s faces the metal plate 6 via the insulating sheet 7. The second heat transfer surface 105s is in surface contact with the insulating sheet 7 so that heat can be transferred between the heat transfer member 105 and the metal plate 6.

The insulating sheet 7 is an insulating member for electrically insulating the metal plate 6 from the wiring board 103. The insulating sheet 7 is disposed between the metal plate 6 and the wiring board 103. The insulating sheet 7 is disposed between the metal plate 6 and the heat transfer member 105. The insulating sheet 7 thermally connects the metal plate 6 and the heat transfer member 105.

The electrical connection unit 101 of the present modified example has the same advantages as the electrical connection unit 1. In addition, compared to the electrical connection unit 1, the electrical connection unit 101 has a longer heat path, but can shorten the electrical path between each terminal 22 of the electronic component 2 and the associated bus bar 135.

### Second modified example and third modified example

In the above-described embodiment, the base plate 31 and the bus bar 35 are integrated in the wiring board 3. However, if the pair of bus bars 35 are fixed to the base plate 31, the base plate 31 and the bus bars 35 may be configured in any manner.

As a second modified example, the base plate 31 and the pair of bus bars 35 may be integrated by, for example, insert-molding.

For example, the wiring board 3 may be formed as a single member by fixing the stud bolt 94 to the bus bar 35 and then insert-molding the bus bar 35 and the base plate 31. That is, the bus bar 35 may be integrated with the base plate 31 without using a fastening member such as a screw or bolt.

As a third modified example, the wiring board 3 may be formed by another structure of the second modified example. For example, the bus bar 35 may be fixed to the base plate 31 by fitting, or may be fixed to the base plate 31 by adhesive or other fixing means. For example, the bus bar 35 may be fixed to the surface of the flat surface portion 32 of the base plate 31 facing the +Z direction from the +Z direction side of the flat surface portion 32 by adhesive or other fixing means.

### Fourth modified example and fifth modified example

In the above-described embodiment, the electrical connection unit 1 includes the pair of connection components 4 and the pair of heat transfer members 5. However, any configuration may be employed as long as heat dissipation properties can be improved.

As a fourth modified example, the electrical connection unit 1 may include only one connection component 4 and only one heat transfer member 5. On the other hand, in the fourth modified example, the wiring board 3 may include only one bus bar 35 and only one fastening member 92.

As a fifth modified example, the electrical connection unit 1 may include three or more connection components 4 and three or more heat transfer members 5. On the other hand, in the fifth modified example, the wiring board 3 may include only three or more bus bars 35 and three or more fastening members 92.

### Sixth modified example

In the embodiment described above, each connection component 4 is a thermal mass block. However, the connection component may be configured in any manner according to a function required for the electrical path. As a sixth modified example, when heat storage is not required in the electrical path, each of the first portion, the second portion, and the third portion of each connection component may have a plate shape.

### Seventh modified example

The base member of the wiring board 3 is not limited to the base plate 31 having the plate-shaped flat surface portion 32. As a seventh modified example, the wiring board 3 may be a base member (for example, an insulating sheet) having the sheet-shaped flat surface portion 32.

### Eighth modified example

The metal plate 6 included in the electrical connection unit 1 is not limited to the metal plate 6 as long as the metal plate is thermally connected to the second heat transfer surface 5s. As an eighth modified example, the electrical connection unit 1 may include, as a metal member, a metal block thermally connected to the second heat transfer surface 5s instead of the metal plate 6.

### Ninth modified example

In the above-described embodiment, each connection component 4 has an L shape when viewed from any of the X direction, the Y direction, and the Z direction. However, each connection component 4 may have any shape as long as the connection component integrally includes the first portion that is fastened to the terminal, the second portion that is in contact with the first heat transfer surface, and the third portion that is fastened to the bus bar.

Several embodiments and modified examples have been described above. However, the embodiments and the modified examples are not limited to the examples described above. For example, the embodiments and the modified examples may be implemented in combination with each other. In addition, Additions, omissions, substitutions, and other modifications can be made without departing from the scope of the present invention. Accordingly, the invention is not to be considered as being limited by the foregoing description and is only limited by the scope of the appended claims.

### REFERENCE SIGNS LIST

1 Electrical connection unit

2 Electronic component

3 Wiring board

4 Connection component

4A Connection component

4B Connection component

5 Heat transfer member

5A Heat transfer member

5B Heat transfer member

5f First heat transfer surface

5s Second heat transfer surface

6 Metal plate (metal member)

7 Insulating sheet

21 Main body

21s Side surface

22 Terminal

22A Terminal

22B Terminal

25 Attachment portion

26 Insulating rib

31 Base plate (base member)

32 Flat surface portion

35 Bus bar

35A Bus bar

35B Bus bar

41 First portion

41h First attachment hole

41s Side surface

42 Second portion

42s Contact surface

43 Third portion

43h Second attachment hole

91 Fastening member

92 Fastening member

93 Fastening member

94 Stud bolt

95 Nut

101 Electrical connection unit

103 Wiring board

104 Connection component

105 Heat transfer member

105f First heat transfer surface

105s Second heat transfer surface

131 Base plate (base member)

132 Flat surface portion

135 Bus bar

141 First portion

142 Second portion

142s Contact surface

143 Third portion

904 Connection component

905 Heat transfer member

935 Bus bar

What is claimed is:

1. An electrical connection unit comprising:
an electronic component including a terminal;
a wiring board including a base member and a bus bar held by the base member and having the electronic component mounted thereon;
a heat transfer member including a first heat transfer surface and a second heat transfer surface;
a metal member thermally connected to the second heat transfer surface; and
a connection component integrally including a first portion fastened to the terminal, a second portion in contact with the first heat transfer surface, and a third portion fastened to the bus bar, and electrically connecting the terminal and the bus bar.

2. The electrical connection unit according to claim 1,
wherein the second portion is in contact with the first heat transfer surface from a first direction, and
wherein the second portion and the third portion are arranged in a second direction intersecting the first direction.

3. The electrical connection unit according to claim 1,
wherein the second portion is closer to the first portion than the third portion.

4. The electrical connection unit according to claim 1,
wherein the electronic component further includes an attachment portion fastened to the wiring board, and
wherein the third portion is closer to the second portion than the attachment portion.

5. The electrical connection unit according to claim 1,
wherein each of the first portion, the second portion, and the third portion has a rectangular parallelepiped block shape.
